(19) United States
(12) Patent Application Publication
(10) Pub. No.: US 2026/0324159 A1
(43) Pub. Date: Oct. 15, 2026

(54) DISPLAY APPARATUS INCLUDING DISPLAY PANEL WITH PAD REGIONS

(71) Applicant: SAMSUNG ELECTRONICS CO., LTD., Suwon-si (KR)

(72) Inventors: Sanguk KIM, Suwon-si (KR); Hyunmin CHO, Suwon-si (KR); Youngjo TAK, Suwon-si (KR)

(73) Assignee: SAMSUNG ELECTRONICS CO., LTD., Suwon-si (KR)

(21) Appl. No.: 19/572,097

(22) Filed: Mar. 19, 2026

(30) Foreign Application Priority Data
Apr. 9, 2025 (KR) 10-2025-0046200

(51) Int. Cl. H10H 29/49; H10H 29/32

(52) U.S. Cl. CPC H10H 29/49; H10H 29/32

(57) ABSTRACT

A display apparatus may include a display panel including: a pixel array structure comprising LED cells configured as sub-pixels, the LED cells being in a display region of the display panel; and a driving circuit substrate on a lower surface of the pixel array structure and comprising a driving circuit configured to drive the LED cells. The display apparatus may further include: a plurality of upper pads on an upper surface of a pad region of the display panel, the pad region being on at least one side of the display region; a plurality of lower pads on a lower surface of the pad region; at least one through-via penetrating the driving circuit substrate and connecting the plurality of lower pads to the driving circuit; an upper flexible circuit layer connecting the plurality of upper pads; and a lower flexible circuit layer connecting the plurality of lower pads.

### CROSS-REFERENCE TO RELATED APPLICATION

This application claims benefit of priority to Korean Patent Application No. 10-2025-0046200, filed on Apr. 9, 2025, in the Korean Intellectual Property Office, the disclosure of which is incorporated herein by reference in its entirety.

### BACKGROUND

### 1. Field

Some embodiments of the present disclosure relate to a display apparatus.

### 2. Description of Related Art

Semiconductor light-emitting diodes (LEDs) may be used as light sources for lighting devices as well as light sources for various electronic products. In particular, the LEDs may be widely used as light sources for various display apparatuses such as a television (TV), a mobile phone, a personal computer (PC), a notebook PC, a personal digital assistant (PDA), or the like.

Some display apparatuses may be mainly comprised of a display panel composed of a liquid crystal display (LCD) and a backlight, but recently, LEDs have been developed in a form that does not require a separate backlight by using LEDs as pixels. Such display apparatuses may be miniaturized, and may implement high-brightness display apparatuses with superior luminous efficiency, compared to LCDs.

### SUMMARY

According to some embodiments of the present disclosure, a display apparatus having superior luminous efficiency may be provided.

Problems to be solved by the present inventive concept are not limited to the problems described above, and other problems not mentioned that are solved by embodiments of the present disclosure can be clearly understood by those skilled in the art from the description below.

According to some embodiments of the present disclosure, a display apparatus may include a display panel including: a pixel array structure including LED cells configured as sub-pixels, the LED cells being in a display region of the display panel; and a driving circuit substrate on a lower surface of the pixel array structure and including a driving circuit configured to drive the LED cells. The display apparatus may further include: a plurality of upper pads on an upper surface of a pad region of the display panel, the pad region being on at least one side of the display region; a plurality of lower pads on a lower surface of the pad region; at least one through-via penetrating the driving circuit substrate and connecting the plurality of lower pads to the driving circuit; a display processor configured to process image information and transmit an image signal to the driving circuit; an upper flexible circuit layer connecting the display processor and the plurality of upper pads; and a lower flexible circuit layer connecting the display processor and the plurality of lower pads.

According to some embodiments of the present disclosure, a display apparatus may include a display panel including: a pixel array structure including LED cells configured as sub-pixels, the LED cells being in a display region of the display panel; and a driving circuit substrate on a lower surface of the pixel array structure and including a driving circuit configured to drive the LED cells. The display apparatus may further include: a plurality of through-electrodes penetrating the pixel array structure in a first pad region of the display panel, connected to the driving circuit, the first pad region being on at least one side of the display region; a plurality of first upper pads on the pixel array structure in the first pad region, the plurality of first upper pads respectively connected to the plurality of through-electrodes; and a plurality of second upper pads connected to the driving circuit and on a portion of the driving circuit substrate in a second pad region of the display panel, the second pad region being adjacent to the first pad region, and the portion of the driving circuit substrate in the second pad region being exposed from the pixel array structure.

According to some embodiments of the present disclosure, a display apparatus may include a display panel including: a pixel array structure including LED cells configured as sub-pixels, the LED cells being in a display region of the display panel; and a driving circuit substrate on a lower surface of the pixel array structure and including a driving circuit configured to drive the LED cells. The display apparatus may further include: a plurality of through-electrodes penetrating the pixel array structure in a first pad region of the display panel, and connected to the driving circuit, the first pad region being on at least one side of the display region; a plurality of first upper pads on an upper surface of the pixel array structure in the first pad region and respectively connected to the plurality of through-electrodes; a plurality of second upper pads connected to the driving circuit and on a portion of an upper surface of the driving circuit substrate in a second pad region of the display panel, the second pad region being adjacent to the first pad region, and the portion of the upper surface of the driving circuit substrate in the second pad region being exposed from the pixel array structure; at least one through-via penetrating the driving circuit substrate; and a plurality of lower pads on a lower surface of the driving circuit substrate and connected to the driving circuit by the at least one through-via.

### BRIEF DESCRIPTION OF DRAWINGS

The above and other aspects, features, and advantages of embodiments of the present disclosure will be more clearly understood from the following detailed description, taken in conjunction with the accompanying drawings, in which:

FIG. 1 is a schematic perspective view of a display apparatus according to an embodiment.

FIG. 2A is an upper perspective view of a display panel that may be employed in the display apparatus of FIG. 1.

FIG. 2B is a lower perspective view of a display panel that may be employed in the display apparatus of FIG. 1.

FIG. 3 is a cross-sectional side view of a portion of the display apparatus of FIG. 1.

FIG. 4A is a cross-section view illustrating a display apparatus before bonding by anisotropic conductive junction layers.

FIG. 4B is a cross-section view illustrating a display apparatus after bonding by anisotropic conductive junction layers.

FIG. 5 is a schematic perspective view of a display apparatus according to an embodiment.

FIG. 6 is a side cross-sectional view of a portion of the display apparatus of FIG. 5.

FIG. 7 is a schematic perspective view of a display apparatus according to an embodiment.

FIG. 8 is a side cross-sectional view of a display apparatus according to an embodiment.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, various non-limiting example embodiments of the present disclosure will be described in detail with reference to the attached drawings.

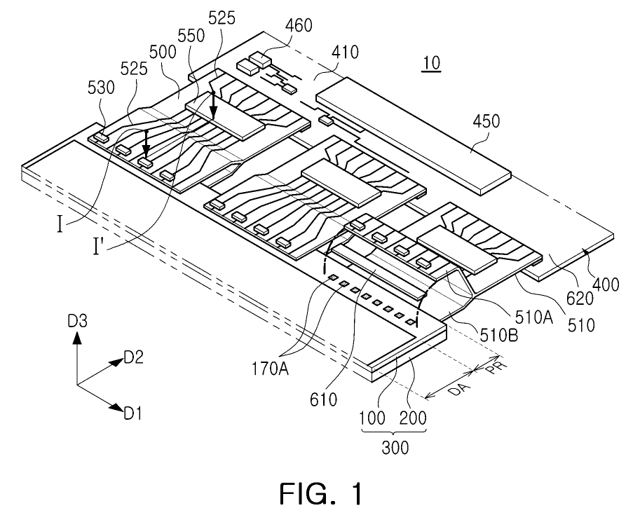

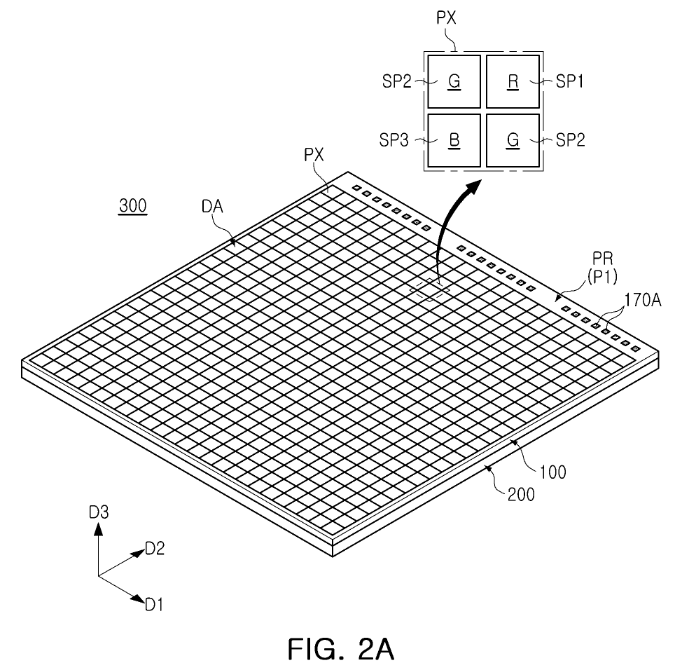

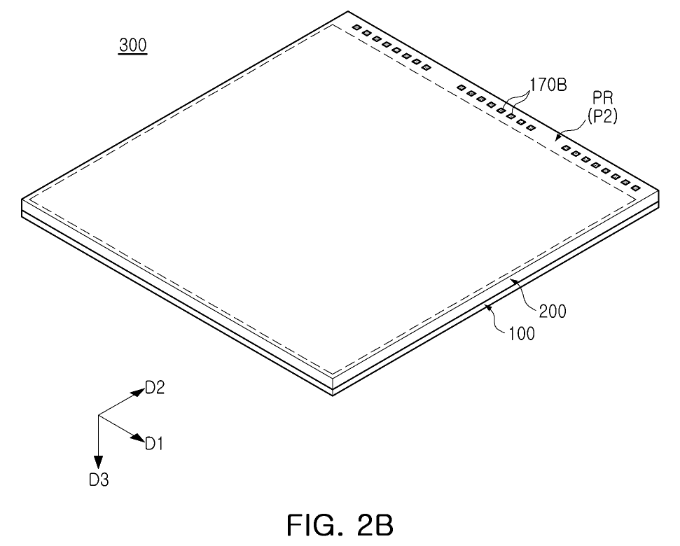

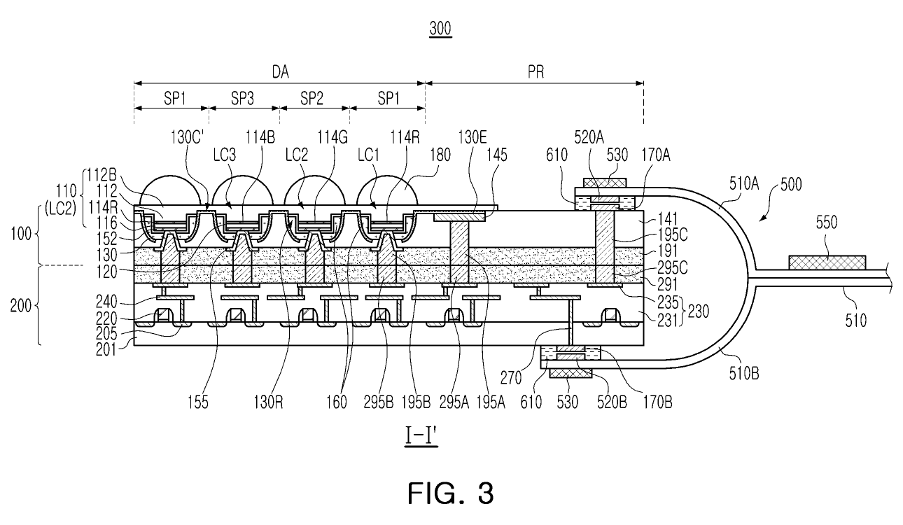

FIG. 1 is a schematic perspective view of a display apparatus according to an embodiment, FIGS. 2A and 2B is an upper perspective view and lower perspective view, respectively, of a display panel that may be employed in the display apparatus of FIGS. 1, and 3 is a cross-sectional side view of a portion of the display apparatus of FIG. 1 taken along a line I-I’.

Referring to FIG. 1, a display apparatus 10 may include a display panel 300, a main board 400 including a processor 450 (e.g., a processor chip), and at least one (e.g., three) multilayer flexible circuit substrate 500 connecting the display panel 300 and the main board 400.

Referring to FIGS. 2A and 2B, together with FIG. 1, the display panel 300 employed in the present embodiment may include a driving circuit substrate 200 including a driving circuit, and a pixel array structure 100 in which a plurality of pixels PX are arranged on the driving circuit substrate 200. In some embodiments, the display panel 300 may further include a frame surrounding the driving circuit substrate 200 and the pixel array structure 100.

The driving circuit substrate 200 may be a structure including the driving circuit including thin film transistor (TFT) cells. In some embodiments, the driving circuit substrate 200 may further include other circuits in addition to the driving circuits for display. In some embodiments, the driving circuit substrate 200 may include a flexible board, and the display apparatus 10 may be implemented as a display apparatus having a curved profile.

The pixel array structure 100 may include a display region DA and a pad region PR located on at least one side of the display region DA. The display region DA may have a plurality of pixels PX arranged for display, and the pixel array structure 100 may be located in the display region DA and include a plurality of LED cells (see FIG. 3) constituting each of the pixels PX. The pad region PR may be provided on at least one side of the display panel 300, and upper pads 170A and the lower pads 170B for connecting to an external device (e.g., processor 450) may be arranged in the pad region PR.

Referring to FIGS. 2A and 3, each of the plurality of pixels PX may include first to third sub-pixels SP1, SP2, and SP3 configured to emit light of different colors to provide a color image. For example, the first to third sub-pixels SP1, SP2, and SP3 may be configured to emit red (R) light, green (G) light, and blue (B) light, respectively.

In each of the pixels PX (also referred to as a “pixel unit”), the first to third sub-pixels SP1, SP2, and SP3 may be arranged in a Bayer pattern. Referring to FIG. 2A, each of the pixels PX may include the first and third sub-pixels SP1 and SP3 (e.g., red (R), blue (B)) arranged in a first diagonal direction with respect to each other, and two second sub-pixels SP2 (e.g., green (G)) arranged in a second diagonal direction with respect to each other, intersecting the first diagonal direction. In the present embodiment, each of the pixels PX are illustrated as having the first to third sub-pixels SP1, SP2, and SP3 arranged in a 2×2 Bayer pattern. However, embodiments of the present disclosure are not limited thereto, and in other embodiments, each of the pixels PX may be configured in another arrangement, such as 3×3, 4×4, or the like. In some embodiments, each of the pixels PX may include a sub-pixel configured to emit a color other than the illustrated colors (red (R), green (G), and blue (B)) such as, for example, yellow light or white light. The pixel array structure 100 of FIG. 2A may include an appropriate number of pixels disposed in columns and rows according to a desired degree of resolution. For example, the plurality of pixels PX may be disposed in 1,024×768 or 1,800×1,350.

The pad region PR employed in the present embodiment may be located in a region adjacent to one side of the display panel 300, and may include an upper pad region P1 and a lower pad region P2, respectively disposed at upper and lower surfaces of the adjacent region. In the present embodiment, the pad region PR is illustrated as being located only on one side of the display panel 300, but is not limited thereto, and in some embodiments, may be disposed on two or more side surfaces of the display panel 300.

Referring to FIG. 2A, a plurality of upper pads 170A may be arranged in the upper pad region P1 adjacent to one side of the display panel 300. The plurality of upper pads 170A may be arranged in a first direction (e.g., direction D1) along an edge adjacent to the one side. In the present embodiment, the plurality of upper pads 170A are illustrated as three groups connected to different multilayer flexible circuit substrates 500, but are not limited thereto, and in some embodiments, the plurality of upper pads 170A may be arranged at the same pitch and connected by a single multilayer flexible circuit substrate 500.

Referring to FIG. 2B, the display panel 300 may include the lower pad region P2 adjacent to one side of the display panel 300 and located at a lower surface corresponding to (e.g., overlapping with) the upper pad region P1. A plurality of lower pads 170B may be disposed in the lower pad region P2.

The plurality of lower pads 170B may be connected to a driving circuit by at least one through-via 270 penetrating the driving circuit substrate 200. Referring to FIG. 3, together with FIG. 2B, the driving circuit substrate 200 may include a device substrate 201 on which semiconductor devices (e.g., source/drain regions 205, driving elements 220, wiring layers 240) are formed, and an interconnection structure 230 having an interconnection layer 235 on the device substrate 201. The semiconductor devices (e.g., source/drain regions 205, driving elements 220, wiring layers 240) and the interconnection layer 235 may constitute a driving circuit for driving a plurality of pixels PX. In the present embodiment, the plurality of lower pads 170B may be connected to a driving circuit (e.g., interconnection layer 235) penetrating the device substrate 201 and a portion (e.g., interconnection insulation layer 231) of the interconnection structure 230. An overall structure of the display panel 300 related thereto will be described later with reference to FIG. 3.

Similar to the plurality of upper pads 170A, the plurality of lower pads 170B may be disposed in the first direction (e.g., direction D1) with respect to each other along an edge adjacent to the one side. In the present embodiment, the plurality of lower pads 170B are illustrated as three groups connected to different multilayer flexible circuit substrates 500, but are not limited thereto, and in some embodiments, the plurality of upper pads 170A may be arranged at the same pitch and connected by a single multilayer flexible circuit substrate 500.

In the present embodiment, the multilayer flexible circuit substrate 500 may connect the display panel 300 and the main board 400. The main board 400 may further include an electronic element relating to the processor 450 (e.g., a processor chip) on a circuit substrate 410. The processor 450 may be configured to process image information and generate an image signal, and the generated image signal may be transmitted to the driving circuit through the multilayer flexible circuit substrate 500.

The multilayer flexible circuit substrate 500 employed in the present embodiment may be a chip-on-film package. The multilayer flexible circuit substrate 500 may include a multilayer flexible circuit layer 510 on which a conductive line 525 is formed, and a display driver integrated circuit (IC) (DDI) 550 on the multilayer flexible circuit layer 510. The multilayer flexible circuit substrate 500 may further include other types of semiconductor chips or passive components 530.

In the present embodiment, the multilayer flexible circuit layer 510 may have a first end portion adjacent to the display panel 300, and a second end portion adjacent to the main board 400. The first end portion of the multilayer flexible circuit layer 510 may be branched into an upper flexible circuit layer 510A and a lower flexible circuit layer 510B, and the second end portion of the multilayer flexible circuit layer 510 may have a multilayer structure in which the upper flexible circuit layer 510A and the lower flexible circuit layer 510B are bonded. In the end portions of the upper flexible circuit layer 510A and the lower flexible circuit layer 510B that are branched, first connection pads 520A and second connection pads 520B may be arranged to correspond to (e.g., overlap with and/or be connected to) the upper pads 170A and the lower pads 170B, respectively.

In the present embodiment, the first connection pads 520A of the upper flexible circuit layer 510A and the second connection pads 520B of the lower flexible circuit layer 510B may be connected to the upper pads 170A and the lower pads 170B of the display panel 300 by an anisotropic conductive film 610, respectively.

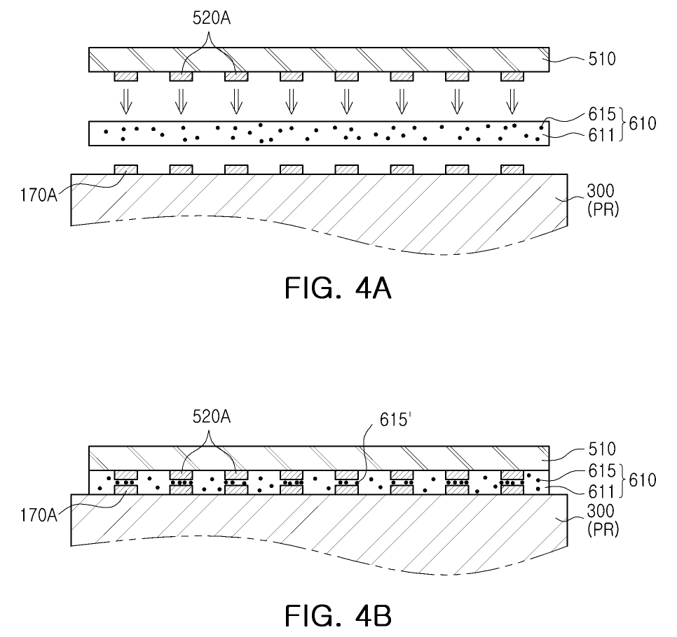

Referring to FIG. 4A, an anisotropic conductive film 610 may include an insulating adhesive layer 611 in which conductive particles 615 are be dispersed. As illustrated in FIG. 4B, an upper flexible circuit layer 510A may be bonded to an upper pad region P1 of a display panel 300 by the anisotropic conductive film 610 by pressing the upper flexible circuit layer 510A toward the upper pad region P1 of a pad region PR, and during this bonding, connection pads 520A and upper pads 170A, facing each other, may be electrically connected to each other in a vertical direction by conductive particles 615, while the first connection pads 520A and the upper pads 170A that are adjacent in a horizontal direction may be insulated from each other in the horizontal direction. Similarly, second connection pads 520B of a lower flexible circuit layer 510B may be connected to lower pads 170B of the display panel 300 by the anisotropic conductive film 610, respectively.

As illustrated in FIG. 1, the second end portion of the multilayer flexible circuit layer 510 may include additional connection pads, and may be respectively connected to bonding pads provided on the main board 400 by another anisotropic conductive film 620.

In the present embodiment, the multilayer flexible circuit substrate 500 is illustrated as being connected to only one side of the display panel 300 in multiple numbers (e.g., three), but is not limited thereto, and in some embodiments, the multilayer flexible circuit substrate 500 may be provided in one or multiple numbers on each of two or more side sides of the display panel 300.

Referring to FIG. 3, a display panel 300 according to the present embodiment may include a driving circuit substrate 200 including driving circuits, and a pixel array structure 100 disposed on the driving circuit substrate 200 and in which a plurality of pixels PX are arranged.

Each of the plurality of pixels PX may include first to third sub-pixels SP1, SP2, and SP3 configured to emit light of different colors from each other to provide a color image. For example, the first to third sub-pixels SP1, SP2, and SP3 may be configured to emit red (R) light, green (G) light, and blue (B) light, respectively. A plurality of LED cells (e.g., first to third LED cells LC1, LC2, and LC3) may be disposed to correspond to (e.g., be within) the first to third sub-pixels SP1, SP2, and SP3, respectively, as micro LED structures. The plurality of LED cells (e.g., first to third LED cells LC1, LC2, and LC3) may be disposed in a plurality of rows and a plurality of columns in a plan view (see FIG. 2A).

The plurality of LED cells (e.g., first to third LED cells LC1, LC2, and LC3) may be provided as light sources for the sub-pixels SP1, SP2, and SP3. The sub-pixels SP1, SP2, and SP3 may be configured to emit light of different colors from each other, as described above. In the present embodiment, the plurality of LED cells (e.g., first LED cells LC1, second LED cells LC2, and third LED cells LC3) may include active layers (e.g., a first active layer 114R, a second active layer 114G, and a third active layer 114B) emitting light of different wavelengths from each other. First LED cells LC1 may include a first active layer 114R configured to emit red light (e.g., light having a wavelength of 620 nm to 660 nm), and may be provided as a red sub-pixel SP1, respectively. Second LED cells LC2 may include a second active layer 114G configured to emit green light (e.g., light having a wavelength of 510 nm to 550 nm), and may be provided as a green sub-pixel SP2, respectively. Third LED cells LC3 may include a third active layer 114B configured to emit blue light (e.g., light having a wavelength of 430 nm to 480 nm), and may be provided as a blue sub-pixel SP3, respectively.

First to third active layers 114R, 114G, and 114B may have different light emitting efficiencies depending on an emission wavelength. To smoothly reproduce a color of the display apparatus 10, an LED cell area may be changed or a configuration of the active layer (e.g., the number of quantum wells) may be changed such that a deviation between amounts of light emitted from different sub-pixels (e.g., the first to third sub-pixels SP1, SP2, and SP3) may be reduced.

The first to third LED cells LC1, LC2, and LC3 may include a semiconductor stack 110 configured to emit light of different wavelengths as described above, and may be provided as a light source for the first to third sub-pixels SP1, SP2, and SP3. The semiconductor stack 110 of the first to third LED cells LC1, LC2, and LC3 employed in the present embodiment may include a nitride epitaxial layer grown on the same substrate.

As illustrated in FIG. 3, the semiconductor stack 110 may have a lower surface facing towards the driving circuit substrate 200, and an upper surface located opposite thereto. In the present embodiment, the semiconductor stack 110 may include a first conductive semiconductor base layer 112B provided as the upper surface of the semiconductor stack 110, and a plurality of LED cells (e.g., first to third LED cells LC1, LC2, and LC3) disposed on a lower surface of the first conductive semiconductor base layer 112B. In this case, an upper surface of the first conductive semiconductor base layer 112B may be provided as a second surface of the semiconductor stack 110 (e.g., a light emitting surface).

The plurality of LED cells (e.g., first to third LED cells LC1, LC2, and LC3) may each include, at least, an active layer (e.g., first to third active layers 114R, 114G, and 114B) and a second conductive semiconductor layer 116 stacked on the lower surface of the first conductive semiconductor base layer 112B. The first conductive semiconductor base layer 112B may be a base layer shared by the first to third LED cells LC1, LC2, and LC3, and may provide a contact region (e.g., an n-side contact region) for driving the plurality of LED cells (e.g., first to third LED cells LC1, LC2, and LC3). In addition, the first conductive semiconductor base layer 112B may have an appropriately small thickness to reduce a light leakage effect. In some embodiments, the thickness of the first conductive semiconductor base layer 112B may be in a range of 0.1 µm to 2 µm.

Each of the plurality of LED cells (e.g., first to third LED cells LC1, LC2, and LC3) employed in the present embodiment may further include a first conductive semiconductor layer 112 between the first conductive semiconductor base layer 112B and the active layer (e.g., the first to third active layers 114R, 114G, and 114B). The first conductive semiconductor layer 112 may be a portion obtained by etching the first conductive semiconductor base layer 112B. The active layers (e.g., the first to third active layers 114R, 114G, and 114B) of each of the first to third LED cells LC1, LC2, and LC3 may be configured to emit light of different wavelengths (e.g., red, green, blue). In the present embodiment, the first to third active layers 114R, 114G, and 114B of each of the first to third LED cells LC1, LC2, and LC3 may include quantum well layers having different indium contents from each other.

The first conductive semiconductor base layer 112B and the first conductive semiconductor layer 112 may each be a nitride epitaxial layer having a composition of n-type InₓAl_{y}Ga_{1-x-y}N (0≤x<1, 0≤y<1, 0≤x+y<1). For example, the first conductive semiconductor layer 112 may be an n-type nitride (e.g., n-GaN) layer doped with silicon (Si), germanium (Ge), or carbon (C). In particular, the first conductive semiconductor base layer 112B may include a high-concentration n-type nitride (n⁺-GaN) layer providing a contact region. The second conductive semiconductor layer 116 may be a nitride semiconductor layer having a composition of p-type InₓAl_{y}Ga_{1-x-y}N (0≤x<1, 0≤y<1, 0≤x+y<1). For example, the second conductive semiconductor layer 116 may be a p-type nitride (p-GaN) layer doped with magnesium (Mg) or zinc (Zn). Each of the first conductive semiconductor layer 112 and the second conductive semiconductor layer 116 may be formed as a single layer, but may also include a plurality of layers having different characteristics such as a doping concentration, a composition, or the like.

The plurality of LED cells (e.g., first to third LED cells LC1, LC2, and LC3) may include a contact electrode 152 located on the second conductive semiconductor layers 116. The contact electrode 152 may include a transparent electrode. The transparent electrode may be a transparent conductive oxide layer or a transparent conductive nitride layer. For example, the transparent electrode may be at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and Zn₍₁₋ₓ₎MgₓO (zinc magnesium oxide, 0≤x≤1).

The first to third LED cells LC1, LC2, and LC3 employed in the present embodiment may have a side surface, nearly perpendicular to the lower surface of the second conductive semiconductor base layer 112B. For example, the side surfaces of the first to third LED cells LC1, LC2, and LC3 may have an inclination angle ranging from 85° to 95°. The side surfaces of the first to third LED cells LC1, LC2, and LC3, nearly perpendicular thereto, may be obtained by an etching process for removing a damaged layer on the side surfaces of the LED cells. This etching process may remove a defective region causing leakage current. In some embodiments, the lower surface (or upper surface of the growth substrate) of the second conductive semiconductor base layer 112B may be a (0001) crystal plane, and the side surfaces of each of the LED cells (e.g., first to third LED cells LC1, LC2, and LC3) may be m-planes. In some embodiments, by applying an additional etching process, the side surfaces of the first to third LED cells LC1, LC2, and LC3 may have an inclination angle of less than 90° with respect to the lower surface of the first conductive semiconductor base layer 112B. Therefore, the LED cells (e.g., first to third LED cells LC1, LC2, and LC3) may have a structure advantageous for light extraction.

The pixel array structure 100 employed in the present embodiment may include a reflective structure configured to emit light to the upper surfaces (e.g., light emitting surfaces) of the first to third LED cells LC1, LC2, and LC3.

This reflective structure may include a spacer 160 having an inclined outer sidewall 160S and a reflective electrode 130 connected to the first conductive semiconductor base layer 112B. In a comparative embodiment, when a reflective electrode is formed along the side surface of the LED cells (e.g., first to third LED cells LC1, LC2, and LC3), perpendicular thereto, light may be trapped within the LED cells (e.g., first to third LED cells LC1, LC2, and LC3) and light may not be effectively extracted at a desired narrow beam angle. However, by introducing the spacer 160 having the inclined outer sidewall (e.g., an inclined side surface) on the side and lower surfaces of the plurality of LED cells (e.g., the first to third LED cells LC1, LC2, and LC3), light extraction efficiency by the reflective electrode 130 may be improved and, further, a light trapping effect may increase. For example, the spacer 160 may include SiO2, SiOC, SiON, or SiOCN.

The reflective electrode 130 may be formed to cover the spacer 160. The reflective electrode 130 may have a reflective surface formed according to the surface shape of the spacer 160. The reflective electrode 130 may have bowl-shaped or bell-shaped reflective structures enhancing a light trapping effect. The reflective electrode 130 may be provided as a first electrode for driving the plurality of LED cells (e.g., first to third LED cells LC1, LC2, and LC3). The reflective electrode 130 may have a contact portion electrically connected to a contact region of the first conductive semiconductor base layer 112B between the plurality of LED cells (e.g., first to third LED cells LC1, LC2, and LC3). The contact region of the first conductive semiconductor base layer 112B may be provided as a region between the plurality of LED cells (e.g., first to third LED cells LC1, LC2, and LC3).

In the present embodiment, the reflective electrode 130 may be provided as a common electrode of the plurality of LED cells (e.g., first to third LED cells LC1, LC2, and LC3). From a planar perspective, as illustrated in FIG. 3, the reflective electrode 130 may have a grid or mesh structure from a planar perspective. A side cross-section of the reflective electrode 130 may have an inverted U shape between adjacent LED cells (e.g., first to third LED cells LC1, LC2, and LC3). The reflective electrode 130 may include a reflective electrode material, and may include at least one from among silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), copper (Cu), titanium (Ti), tantalum (Ta), and tungsten (W). In some embodiments, the reflective electrode 130 may include a single-layer or multi-layer structure.

The pixel array structure 100 may further include a gapfill insulating layer 141 covering the reflective electrode 130 on the lower surface of the semiconductor stack 110. The gapfill insulating layer 141 may include a spin-on hardmask (SOH), a flowable dielectric (FOX), Tonen silazane (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), a high density plasma (HDP) oxide, a plasma enhanced oxide (PEOX), a flowable chemical vapor deposition (CVD) (FCVD) oxide, or a combination thereof. The gapfill insulating layer 141 may be formed using a chemical vapor deposition, a flowable CVD process, or a spin coating process, respectively. The gapfill insulating layer 141 may be formed to have a flat upper surface. In some embodiments, even when the gapfill insulating layer 141 includes a same material as a material of the spacer 160 (e.g., silicon oxide), the spacer 160 may be formed to have a denser structure than a structure of the gapfill insulating layer 141. For example, such a spacer 160 that is dense may be formed by a process such as atomic layer deposition (ALD).

Connection electrodes 155 may be respectively connected to contact electrodes 152 of the plurality of LED cells (e.g., first to third LED cells LC1, LC2, and LC3). In the present embodiment, the connection electrodes 155 may be used as another electrode for driving the plurality of LED cells (e.g., first to third LED cells LC1, LC2, and LC3), together with the reflective electrode 130, and, unlike the reflective electrode 130 which may be a common electrode, may be provided as individual electrodes. In some embodiments, the connection electrode 155 may include an electrode material similar to an electrode material of the reflective electrode 130. For example, the connection electrode 155 may include at least one from among silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), copper (Cu), titanium (Ti), tantalum (Ta), and tungsten (W). In some embodiments, the connection electrode 155 may include a single-layer or multi-layer structure.

Referring to FIG. 3, the reflective electrode 130 may have an extension portion 130E extending from the display region DA to the pad region PR. A common electrode 145 may be disposed on the extension portion 130E of the reflective electrode 130.

An upper bonding structure may be provided and include an upper bonding insulating layer 191 disposed on a lower surface of the gapfill insulating layer 141, and upper bonding electrodes (e.g., first to third upper bonding electrodes 195A, 195B, and 195C) electrically connected to each of the reflective electrode 130 and the connection electrodes 155 on the upper bonding insulating layer 191. At least some of the upper bonding electrodes 195 may be electrically connected to the reflective electrode 130 and the connection electrodes 155. At least some of the upper bonding electrodes (e.g., first to third upper bonding electrodes 195A, 195B, and 195C) may have a shape such as a post. Upper surfaces of at least some of the upper bonding electrodes (e.g., first to third upper bonding electrodes 195A, 195B, and 195C) may have a substantially flat coplanar surface with an upper surface of the upper bonding insulating layer 191. This flat coplanar surface may be provided as a bonding surface for bonding to the driving circuit substrate 200 as a lower surface of the pixel array structure 100. The upper bonding electrodes (e.g., first to third upper bonding electrodes 195A, 195B, and 195C) may include a conductive material such as, for example, copper (Cu). For example, the upper bonding insulating layer 191 may include at least one from among SiO, SiN, SiCN, SiOC, SiON, and SiOCN.

As described above, the common electrode 145 may be provided as a common electrode structure for driving the LED cells (e.g., first to third LED cells LC1, LC2, and LC3) together with the reflective electrode 130. The common electrode 145 may include a conductive material such as, for example, at least one from among silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and gold (Au).

In the present embodiment, depending on a connection target, the upper bonding electrodes may include a first upper bonding electrode 195A electrically connected to the reflective electrode 130, second upper bonding electrodes 195B electrically connected to the connection electrodes 155, and a third upper bonding electrode 195C connected to the upper pad 170A.

Referring to FIG. 3, the first upper bonding electrode 195A may penetrate the upper bonding insulating layer 191 and the gapfill insulating layer 141 to contact the common electrode 145, and may be commonly connected on one side (particularly, the first conductive semiconductor base layer 112B) of each of the LED cells (e.g., first to third LED cells LC1, LC2, and LC3) through the common electrode 145 and the reflective electrode 130. The second upper bonding electrodes 195B may penetrate the upper bonding insulating layer 191 to contact the connection electrodes 155, and may be individually connected on the other side (particularly, the second conductive semiconductor layer 116) of each of the LED cells (e.g., first to third LED cells LC1, LC2, and LC3) through the connection electrodes 155 and the contact electrodes 152. In addition, at least one third upper bonding electrode 195C may penetrate the upper bonding insulating layer 191 and the gapfill insulating layer 141 to contact at least one upper pad 170A, and the upper pads 170A may be connected to the main board 400, which may be an external device, through the multilayer flexible circuit substrate 500, as described above.

As such, in the present embodiment, the third upper bonding electrodes 195C may be provided as electrodes penetrating the pixel array structure 100 (e.g., the gapfill insulating layer 141), and the upper pads 170A may be disposed on the upper surface of the pixel array structure 100 in the pad region PR, and may be respectively connected to the third upper bonding electrodes 195C.

Referring to FIG. 3, a driving circuit substrate 200 employed in the present embodiment may include a device substrate 201 on which driving elements 220 for a driving circuit are disposed, and a lower bonding structure disposed on the device substrate 201. The driving circuit substrate 200 may include an interlayer connection structure (e.g., the interconnection structure 230) between the device substrate 201 and the lower bonding structure. The interlayer connection structure (e.g., the interconnection structure 230) may include an interconnection insulation layer 231 on the device substrate 201, and an interconnection layer 235 electrically connected to the driving elements 220 in the interconnection insulation layer 231. The semiconductor devices (e.g., the driving elements 220) for a driving circuit may include thin film transistor (TFT) cells.

The device substrate 201 may be a semiconductor substrate including impurity regions including source/drain regions 205. The device substrate 201 may include, for example, a semiconductor such as silicon (Si) or germanium (Ge), or a compound semiconductor such as SiGe, SiC, GaAs, InAs, or InP. The driving circuit may include a circuit for controlling driving of pixels, particularly sub-pixels. A source/drain region 205 (e.g., a source region) of the TFT cells may be electrically connected to one side of the LED cells (e.g., first to third LED cells LC1, LC2, and LC3) through the interlayer connection structure (e.g., the interconnection structure 230) and the lower bonding structure. For example, a source/drain region 205 (e.g., a drain region) of the TFT cells may be connected to a data line through an interconnection circuit (e.g., the interconnection layer 235). The gate electrodes of the TFT cells may be connected to the gate line through the interconnection circuit (e.g., the interconnection layer 235).

The lower bonding structure may include a lower bonding insulating layer 291 and lower bonding electrodes (e.g., first to third lower bonding electrodes 295A, 295B, and 295C) disposed in the lower bonding insulating layer 291 and electrically connected to a driving circuit. The lower bonding electrodes (e.g., first to third lower bonding electrodes 295A, 295B, and 295C) may be electrically connected to the driving circuit through the interconnection layer 235. For example, the lower bonding electrodes (e.g., first to third lower bonding electrodes 295A, 295B, and 295C) may be provided in a pillar structure. Upper surfaces of the lower bonding electrodes (e.g., first to third lower bonding electrodes 295A, 295B, and 295C) may have a substantially flat coplanar surface with an upper surface of the lower bonding insulating layer 291. This coplanar surface may be provided as a bonding surface for bonding to the pixel array structure 100 as an upper surface of the driving circuit substrate 200. The lower bonding electrodes (e.g., first to third lower bonding electrodes 295A, 295B, and 295C) may include a conductive material such as, for example, copper (Cu). For example, the lower bonding insulating layer 291 may include at least one from among SiO, SiN, SiCN, SiOC, SiON, or SiOCN.

The lower bonding electrodes (e.g., first to third lower bonding electrodes 295A, 295B, and 295C) of the driving circuit substrate 200 and the upper bonding electrodes (e.g., first to third upper bonding electrodes 195A, 195B, and 195C) of the pixel array structure 100 may be bonded to each other to provide an electrical connection path between the driving circuit substrate 200 and the pixel array structure 100. In addition, the upper bonding insulating layer 191 of the pixel array structure 100 may be bonded to the lower bonding insulating layer 291 of the driving circuit substrate 200.

In this manner, the driving circuit substrate 200 and the pixel array structure 100 may be coupled to each other by bonding of the lower bonding electrodes (e.g., first to third lower bonding electrodes 295A, 295B, and 295C) and the upper bonding electrodes (e.g., first to third upper bonding electrodes 195A, 195B, and 195C) and bonding of the lower bonding insulating layer 291 and the upper bonding insulating layer 191. The bonding of the lower bonding electrodes (e.g., first to third lower bonding electrodes 295A, 295B, and 295C) and the upper bonding electrodes (e.g., first to third upper bonding electrodes 195A, 195B, and 195C) may be, for example, copper (Cu)-copper (Cu) bonding, and the bonding of the lower bonding insulating layer 291 and the upper bonding insulating layer 191 may be dielectric-dielectric bonding such as, for example, dielectric-dielectric bonding such as SiCN-SiCN bonding. The driving circuit substrate 200 and the pixel array structure 100 may be bonded by hybrid bonding including the copper (Cu)-copper (Cu) bonding and the dielectric-dielectric bonding, and may be bonded without a separate adhesive layer.

Depending on a connection target, similarly to the upper bonding electrodes (e.g., first to third upper bonding electrodes 195A, 195B, and 195C), the lower bonding electrodes may be divided into first to third lower bonding electrodes 295A, 295B, and 295C, respectively. Specifically, the first lower bonding electrode 295A may be bonded to the first upper bonding electrode 195A to electrically connect the reflective electrode 130 to the driving circuit via the common electrode 145. The second lower bonding electrodes 295B may be bonded to the second upper bonding electrodes 195B, respectively, to electrically connect the connection electrodes 155, which may be individual electrodes, to the driving circuit.

In this manner, by bonding of the first upper bonding electrodes 195A and the first lower bonding electrodes 295A and by bonding of the second upper bonding electrodes 195B and the second lower bonding electrodes 295B, the plurality of LED cells (e.g., first to third LED cells LC1, LC2, and LC3) may be individually driven and connected to the driving circuit. In addition, the third lower bonding electrodes 295C may be each bonded to the third upper bonding electrodes 195C, and the upper pads 170A disposed on an upper surface of the pad region PR (e.g., upper pad region P1), e.g., an upper surface of the pixel array structure 100, may be electrically connected to the driving circuit by this bonding. In this manner, in the present embodiment, the upper pads 170A may be disposed on an upper surface of the gapfill insulating layer 141 in the pad region PR.

As described above, the plurality of lower pads 170B disposed on a lower surface of the pad region PR (e.g., the lower pad region P2) may be connected to the driving circuit by at least one through-via 270 penetrating the driving circuit substrate 200.

Referring to FIG. 3, micro lenses 180 may be disposed on each of the LED cells (e.g., first to third LED cells LC1, LC2, and LC3) to focus light emitted from the LED cells (e.g., first to third LED cells LC1, LC2, and LC3). The micro lenses 180 may be configured to adjust the beam angle of light emitted from the LED cells (e.g., first to third LED cells LC1, LC2, and LC3). In the present embodiment, the micro lenses 180 may be disposed on the first conductive semiconductor base layer 112B. The micro lenses 180 may be formed as, for example, a transparent photoresist material film or a transparent thermosetting resin film. As an example, the micro lenses 180 employed in the present embodiment may be provided in the same shape and size as each other, but in some embodiments, may have different shapes and/or different sizes from each other depending on areas of the first to third LED cells (e.g., first to third LED cells LC1, LC2, and LC3).

In this manner, the display panel 300 employed in the present embodiment may arrange the required number of input/output pads across the upper surface of the pad region PR (e.g., the upper pad region P1) and the lower surface of the pad region PR (e.g., the lower pad region P2). The upper pads 170A may be arranged in the upper pad region P1 and the lower pads 170B may be arranged in the lower pad region P2, to secure an arrangement space for the required number of input/output pads for driving despite the ultra-small display panel 300.

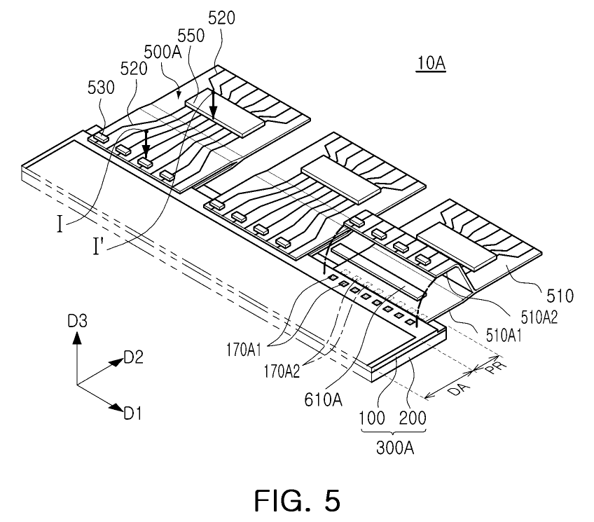

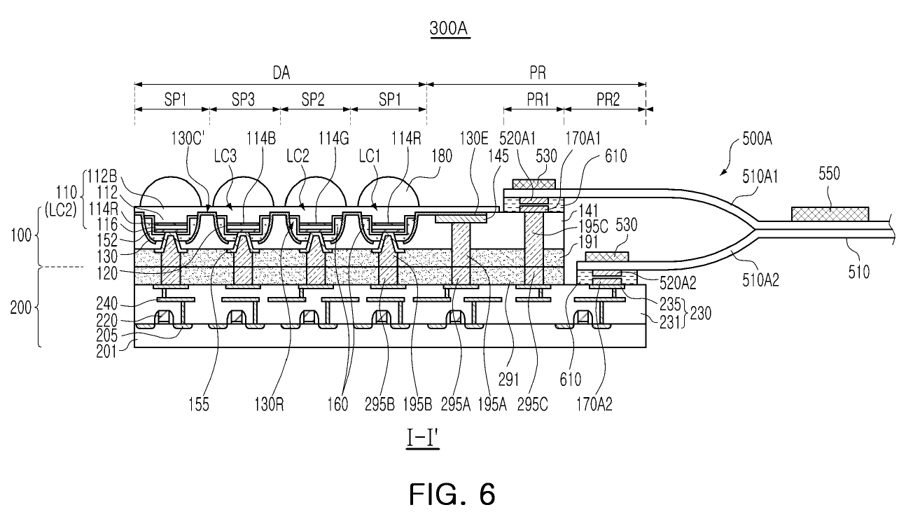

FIG. 5 is a schematic perspective view of a display apparatus according to an embodiment, and FIG. 6 is a side cross-sectional view of a portion of the display apparatus of FIG. 5 taken along the line I-I’.

Referring to FIGS. 5 and 6, it can be understood that a display apparatus 10A according to the present embodiment is similar to the display apparatus 10 illustrated in FIGS. 1 to 4B, except that, instead of having a lower pad region P2 like the previous embodiment, a first pad region PR1 and a second pad region PR2 may be provided in a stepped manner with respect to each other on an upper surface of a pad region PR. In the first pad region PR1 and the second pads region PR2, first upper pads 170A1 and second upper pads 170A2 may be respective disposed, and the first upper pads 170A1 and the second upper pads 170A2 may be respectively connected to a first upper flexible circuit layer 510A1 and a second upper flexible circuit layer 510A2. In addition, unless otherwise specifically described, components of the present embodiment can be understood with reference to the description of the same or similar components of the display apparatus 10 illustrated in FIGS. 1 to 4B.

The pad region PR of a display panel 300A employed in the present embodiment may be divided into the first pad region PR1 and the second pad region PR2. The first pad region PR1 and the second pads region PR2 may have a stepped structure. Specifically, in the first pad region PR1, similarly to the upper pad region (e.g., the upper pad region P1 of FIGS. 1 and 3) of the previous embodiment, a third upper bonding electrode 195C may be configured to penetrate a pixel array structure 100, particularly a gapfill insulating layer 141, and be electrically connected to a driving circuit. In the second pad region PR2, a portion of the pixel array structure 100, particularly a portion of the gapfill insulating layer 141 and portions of upper bonding structure and the lower bonding structure, may be removed to expose an upper surface region of the driving circuit substrate 200. The first pad region PR1 and the second pad region PR2 may have a stepped difference equal to a thickness of the removed portion of the pixel array structure 100.

In the present embodiment, the pad region PR may be adjacent to an edge of at least one side of the display panel 300A, and the second pad region PR2 may be disposed to be closer to the edge than the first pad region PR1. Specifically, the second pad region PR2 may be formed along the edge.

In the first pad region PR1, the first upper pads 170A1 may be disposed on an upper surface of the pixel array structure 100, and may be respectively connected to third upper bonding electrodes 195C, which may be through-electrodes. In the second pad region PR2, second upper pads 170A2 may be disposed on an exposed upper surface region of the driving circuit substrate 200, and may be electrically connected to a driving circuit.

In this manner, the first upper pads 170A1 and the second upper pads 170A2 may be respectively disposed in the first pad regions PR1 and the second pads regions PR2 of different levels by utilizing the stepped difference.

In this stepped structure, the first upper flexible circuit layer 510A1 may electrically connect a display processor (e.g., the processor 450 of FIG. 1) and the first upper pads 170A1, and the second upper flexible circuit layer 510A2 may electrically connect the display processor (e.g., the processor 450 of FIG. 1) and the second upper pads 170A2. The first upper flexible circuit layer 510A1 and the second upper flexible circuit layer 510A2 may be provided as a multilayer flexible circuit substrate 500A in which a portion adjacent to a main board (e.g., the main board 400 of FIG. 1) is stacked, similar to the previous embodiment.

The first upper pads 170A1 (and the second upper pads 170A2) may be disposed with respect to each other in a first direction (e.g., direction D1) along an edge adjacent to the at least one side, and the first upper pads 170A1 may be disposed to overlap with the second upper pads 170A2 in a second direction (e.g., direction D2), perpendicular to the first direction (e.g., direction D1).

In the present embodiment, a plurality of first upper pads 170A1 may be divided into three groups, and may be respectively connected to different first upper flexible circuit layers 500A1, and a plurality of second upper pads 170A2 may be divided into three groups, and may be respectively connected to different second upper flexible circuit layers 500A2. Although not limited thereto, each of the groups of the first upper pads 170A1 and the second upper pads 170A2 may be disposed to overlap in the second direction (e.g., direction D2).

The display panel 300A according to the present embodiment may secure a pad region PR for a required number of input/output pads by implementing the pad region PR adjacent to at least one side, as the first pad regions PR1 and the second pads regions PR2 having a stepped difference, even when the display panel 300A is miniaturized.

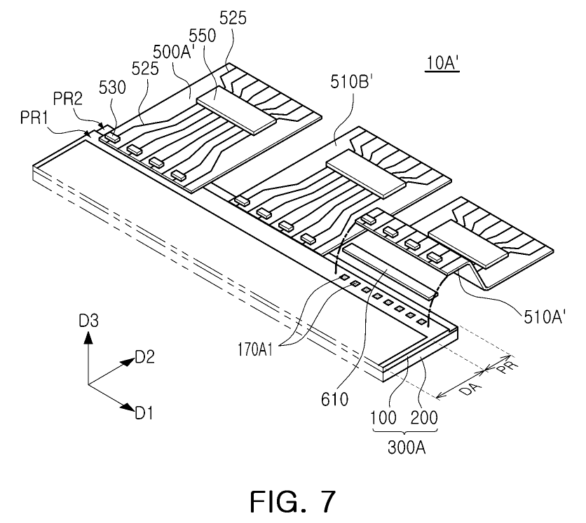

FIG. 7 is a schematic perspective view of a display apparatus according to an embodiment.

Referring to FIG. 7, it can be understood that a display apparatus 10A’ according to the present embodiment is similar to the display apparatus 10A illustrated in FIGS. 5 and 6, except that first upper pads 170A1 arranged in a first pad region PR1 and second upper pads 170A2 arranged in a second pad region PR2 are arranged not to overlap with each other, and a first upper flexible circuit layer 510A’ and a second upper flexible circuit layer 510B’ are arranged not to intersect in the second direction (e.g., D2). In addition, unless otherwise specifically described, components of the present embodiment can be understood with reference to the description of the same or similar components of the display apparatus 10A illustrated in FIGS. 5 and 6.

Similar to the previous embodiment, the first pad region PR1 and the second pad region PR2, having a stepped difference, may be provided. The first upper pads 170A1 arranged in the first pad region PR1 and second upper pads arranged in the second pad region PR2 may be arranged not to overlap in the second direction (e.g., direction D2). This is not limited thereto, and in some embodiments, the first upper pads 170A1 and the second upper pads 170A2 may be arranged to overlap only in some regions. In the present embodiment, the first upper flexible circuit layer 510A’ and the second upper flexible circuit layer 510B’ may each be provided as a single-layer structure.

In some embodiments, the display panel illustrated in FIGS. 1 and 3 may have an upper pad region having a different structure. For example, an upper pad region P1 may not be provided as an upper surface of a pixel array structure 100, particularly a gapfill insulating layer 141, but may be provided as an open upper surface region of a driving circuit substrate 200 by removing a portion of the pixel array structure 100, similar to the second pad region of FIG. 7.

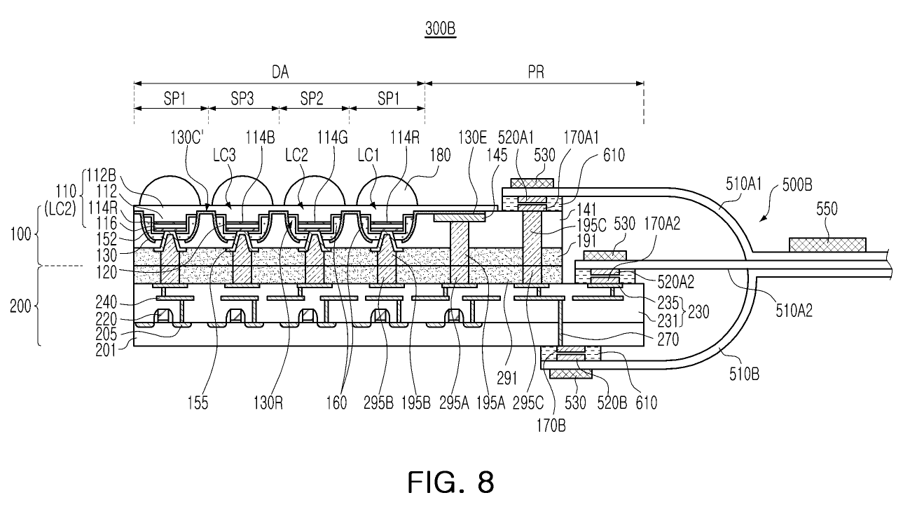

FIG. 8 is a side cross-sectional view of a display apparatus according to an embodiment.

Referring to FIG. 8, it can be understood that a display apparatus according to the present embodiment is similar to the display apparatus 10 illustrated in FIGS. 1 to 4B, except that a first pad region PR1 and a second pad region PR2 are formed using a stepped difference in an upper pad region P1 while maintaining a lower pad region P2, as in the embodiments of FIGS. 1 and 3, first upper pads 170A1 and second upper pads 170A2 may be disposed in a first pad region PR1 and a second pad region PR2 (see FIG. 6), respectively, and the first upper pads 170A1 and the second upper pads 170A2 may be connected to a first upper flexible circuit layer 510A1 and a second upper flexible circuit layer 510A2, respectively. In addition, unless otherwise specifically described, components of the present embodiment can be understood with reference to the description of the same or similar components of the display apparatuses illustrated in FIGS. 1 to 6.

A pad region PR of a display panel 300B employed in the present embodiment may include the lower pad region, together with the first pad region PR1 and the second pad region PR2 (see FIG. 6) having a stepped structure. Similar to the embodiment illustrated in FIGS. 5 and 6, in the first pad region PR1, a third upper bonding electrode 195C may penetrate a pixel array structure 100, particularly a gapfill insulating layer 141, and may be configured to be electrically connected to a driving circuit, and in the second pad region PR2, a portion of the pixel array structure 100, particularly a portion of the gapfill insulating layer 141 and portions of the upper bonding structure and the lower bonding structure, may be removed to expose an upper surface region of a driving circuit substrate 200.

In addition, the lower pad region may be provided as a lower surface region adjacent to one side of the display panel 300, and a plurality of lower pads 170B may be disposed along an edge of the lower pad region. The plurality of lower pads 170B may be connected to the driving circuit by at least one through-via 270 penetrating the driving circuit substrate 200.

One end of the first upper flexible circuit layer 510A1 may be electrically connected to the first upper pads 170A1 using an anisotropic conductive film 610, and similarly, one end of the second upper flexible circuit layer 510A2 may be electrically connected to the second upper pads 170A2 using the anisotropic conductive film 610. In addition, a lower flexible circuit layer 510B may be electrically connected to the lower pads 170B using the anisotropic conductive film 610.

The other ends of the first upper flexible circuit layer 510A1 and the second upper flexible circuit layer 510A2 and the other end of the lower flexible circuit layer 510B may be electrically connected to a main board (e.g., the main board 400 in FIG. 1) using an anisotropic conductive film, and portions adjacent to the other ends may be provided as a stacked multilayer flexible circuit substrate 500B stacked to each other.

According to some embodiments of the present disclosure, a method of manufacturing the display apparatus may be provided. The method may include: obtaining (e.g., manufacturing) a display panel; providing a plurality of upper pads on an upper surface of a pad region of the display panel, the pad region being on at least one side of the display region; providing a plurality of lower pads on a lower surface of the pad region; connecting a display processor to the plurality of upper pads with an upper flexible circuit layer; and connecting the display processor to the plurality of lower pads with a lower flexible circuit layer. The display apparatus may include a pixel array structure including LED cells configured as sub-pixels, the LED cells being in a display region of the display panel; and a driving circuit substrate on a lower surface of the pixel array structure and including a driving circuit configured to drive the LED cells. The display panel may further include least one through-via penetrating the driving circuit substrate and connecting the plurality of lower pads to the driving circuit.

According to some embodiments of the present disclosure, the pixel array structure may further include a plurality of through-electrodes penetrating the pixel array structure in the pad region and connected to the driving circuit, and wherein the plurality of upper pads may be on an upper surface of the pixel array structure in the pad region, and may be respectively connected to the plurality of through-electrodes.

According to some embodiments of the present disclosure, an upper surface region of the driving circuit substrate may be exposed from the pixel array structure in the pad region, and wherein the plurality of upper pads may be on the upper surface region of the driving circuit substrate, and may be connected to the driving circuit.

According to some embodiments of the present disclosure, the method may include connecting a multilayer flexible circuit substrate to the display panel, wherein the multilayer flexible circuit substrate includes the upper flexible circuit layer and the lower flexible circuit layer.

According to the above-described embodiments, an upper surface region and a lower surface region of a display panel and/or a plurality of upper surface regions having a stepped difference may be provided as regions for pads to secure a pad region of sufficient area even in an ultra-miniaturized display apparatus.

Various advantages and effects of embodiments of the present disclosure are not limited to the above-described contents, and other advantages and effects of embodiments of the present disclosure may be understood by persons of ordinary skill in the art.

While non-limiting example embodiments have been described above with reference to the accompanying drawings, it will be apparent to those skilled in the art that modifications and variations could be made without departing from the scope of the present disclosure.

What is claimed is:

1. A display apparatus comprising:
a display panel comprising:
a pixel array structure comprising LED cells configured as sub-pixels, the LED cells being in a display region of the display panel; and
a driving circuit substrate on a lower surface of the pixel array structure and comprising a driving circuit configured to drive the LED cells;
a plurality of upper pads on an upper surface of a pad region of the display panel, the pad region being on at least one side of the display region;
a plurality of lower pads on a lower surface of the pad region;
at least one through-via penetrating the driving circuit substrate and connecting the plurality of lower pads to the driving circuit;
a display processor configured to process image information and transmit an image signal to the driving circuit;
an upper flexible circuit layer connecting the display processor and the plurality of upper pads; and
a lower flexible circuit layer connecting the display processor and the plurality of lower pads.

2. The display apparatus of claim 1, wherein the pixel array structure further comprises a plurality of through-electrodes penetrating the pixel array structure in the pad region and connected to the driving circuit, and
wherein the plurality of upper pads are on an upper surface of the pixel array structure in the pad region, and are respectively connected to the plurality of through-electrodes.

3. The display apparatus of claim 1, wherein an upper surface region of the driving circuit substrate is exposed from the pixel array structure in the pad region, and
wherein the plurality of upper pads are on the upper surface region of the driving circuit substrate, and are connected to the driving circuit.

4. The display apparatus of claim 1, wherein the display panel further comprises a multilayer flexible circuit substrate that comprises the upper flexible circuit layer and the lower flexible circuit layer.

5. The display apparatus of claim 1, wherein the pad region comprises a first pad region and a second pad region,
wherein the pixel array structure further comprises through-electrodes penetrating the pixel array structure in the first pad region and connected to the driving circuit,
wherein an upper surface region of the driving circuit substrate is exposed from the pixel array structure in the second pad region, and
wherein the plurality of upper pads comprise:
first upper pads on an upper surface of the pixel array structure in the first pad region and respectively connected to the through-electrodes, and
second upper pads on the upper surface region of the driving circuit substrate in the second pad region and connected to the driving circuit.

6. The display apparatus of claim 5, wherein the upper flexible circuit layer comprises:
a first upper flexible circuit layer connecting the display processor and the first upper pads, and
a second upper flexible circuit layer connecting the display processor and the second upper pads.

7. The display apparatus of claim 5, wherein the first upper pads are arranged in a first direction along an edge adjacent to the at least one side, and
wherein the second upper pads are arranged in the first direction along the edge, and
wherein at least one first upper pad among the first upper pads overlap with at least second upper pad among the second upper pads in a second direction, perpendicular to the first direction.

8. The display apparatus of claim 1, wherein the upper flexible circuit layer comprises a plurality of connection pads connected to the plurality of upper pads, and
wherein the display apparatus further comprises a anisotropic conductive film that bonds the upper flexible circuit layer to the upper surface of the pad region and connects the plurality of upper pads and the plurality of connection pads, respectively.

9. The display apparatus of claim 1, wherein the lower flexible circuit layer comprises a plurality of connection pads connected to the plurality of lower pads, and
wherein the display apparatus further comprises a anisotropic conductive film that bonds the lower flexible circuit layer to the lower surface of the pad region and connects the plurality of lower pads and the plurality of connection pads, respectively.

10. The display apparatus of claim 9, wherein the pixel array structure further comprises a first conductive semiconductor base layer comprising an upper surface, configured as a light emitting surface, and a lower surface on which the LED cells are arranged, and
wherein each of the LED cells comprises an active layer and a conductive semiconductor layer sequentially stacked on the lower surface of the first conductive semiconductor base layer.

11. The display apparatus of claim 10, wherein the LED cells comprise a first LED cell, a second LED cell, and a third LED cell,
wherein the first LED cell, the second LED cell, and the third LED cell are configured to emit light of a different color with respect to each other.

12. The display apparatus of claim 10, wherein the pixel array structure further comprises an additional conductive semiconductor layer on an upper surface of the active layer,
wherein the each of the LED cells comprises:
an individual electrode on the lower surface of the conductive semiconductor layer; and
a portion of a common electrode connected to the additional conductive semiconductor layer, and
wherein the individual electrode and the common electrode are connected to the driving circuit.

13. The display apparatus of claim 1, wherein the driving circuit substrate further comprises:
a device substrate on which semiconductor devices constituting the driving circuit are disposed; and
an interconnection structure on the device substrate, the interconnection structure comprising an interconnection layer connected to the LED cells and the semiconductor devices.

14. The display apparatus of claim 13, wherein
the driving circuit substrate further comprises a first bonding structure comprising:
a first bonding insulating layer on the device substrate; and
first bonding electrodes in the first bonding insulating layer and connected to the driving circuit, and
the pixel array structure further comprises a second bonding structure comprising:
a second bonding insulating layer bonded to the first bonding insulating layer; and
second bonding electrode in the second bonding insulating layer, connected to the LED cells, and respectively bonded to the first bonding electrodes.

15. A display apparatus comprising:
a display panel comprising:
a pixel array structure comprising LED cells configured as sub-pixels, the LED cells being in a display region of the display panel; and
a driving circuit substrate on a lower surface of the pixel array structure and comprising a driving circuit configured to drive the LED cells;
a plurality of through-electrodes penetrating the pixel array structure in a first pad region of the display panel, connected to the driving circuit, the first pad region being on at least one side of the display region;
a plurality of first upper pads on the pixel array structure in the first pad region, the plurality of first upper pads respectively connected to the plurality of through-electrodes; and
a plurality of second upper pads connected to the driving circuit and on a portion of the driving circuit substrate in a second pad region of the display panel, the second pad region being adjacent to the first pad region, and the portion of the driving circuit substrate in the second pad region being exposed from the pixel array structure.

16. The display apparatus of claim 15, wherein the second pad region is closer than the first pad region to an edge of the display panel.

17. The display apparatus of claim 16, wherein
the plurality of first upper pads are arranged with respect to each other in a first direction along the edge,
the plurality of second upper pads are arranged with respect to each other in the first direction along the edge, and
at least one of the plurality of first upper pads overlaps with at least one of the plurality of second upper pads in a second direction that crosses the first direction.

18. The display apparatus of claim 15, further comprising:
a display processor configured to process image information and transmit an image signal to the driving circuit;
a first upper flexible circuit layer connecting the display processor and the plurality of first upper pads; and
a second upper flexible circuit layer connecting the display processor and the plurality of second upper pads.

19. The display apparatus of claim 15, wherein the driving circuit substrate further comprises:
a device substrate on which semiconductor devices constituting the driving circuit are disposed;
an interconnection structure comprising:
an interconnection layer connected to the LED cells and the semiconductor devices on the device substrate; and
a first bonding structure comprising a first bonding insulating layer on the device substrate, and first bonding electrodes in the first bonding insulating layer and connected to the interconnection layer, and
the pixel array structure further comprises a second bonding structure comprising:
a second bonding insulating layer bonded to the first bonding insulating layer; and
second bonding electrodes in the second bonding insulating layer, connected to the LED cells, and respectively bonded to the first bonding electrodes.

20. A display apparatus comprising:
a display panel comprising:
a pixel array structure comprising LED cells configured as sub-pixels, the LED cells being in a display region of the display panel; and
a driving circuit substrate on a lower surface of the pixel array structure and comprising a driving circuit configured to drive the LED cells;
a plurality of through-electrodes penetrating the pixel array structure in a first pad region of the display panel, and connected to the driving circuit, the first pad region being on at least one side of the display region;
a plurality of first upper pads on an upper surface of the pixel array structure in the first pad region and respectively connected to the plurality of through-electrodes;
a plurality of second upper pads connected to the driving circuit and on a portion of an upper surface of the driving circuit substrate in a second pad region of the display panel, the second pad region being adjacent to the first pad region, and the portion of the upper surface of the driving circuit substrate in the second pad region being exposed from the pixel array structure;
at least one through-via penetrating the driving circuit substrate; and
a plurality of lower pads on a lower surface of the driving circuit substrate and connected to the driving circuit by the at least one through-via.
